(19) United States
(12) Patent Application Publication
(10) Pub. No.: US 2024/0373520 A1
(43) Pub. Date: Nov. 7, 2024

(54) HOUSEHOLD APPLIANCE AND OPERATING METHOD THEREOF

(71) Applicant: ELECTROLUX APPLIANCES AKTIEBOLAG, Stockholm (SE)

(72) Inventor: Luca RIZZO, Porcia (IT)

(21) Appl. No.: 18/285,844

(22) PCT Filed: Apr. 8, 2021
(86) PCT No.: PCT/EP2021/059222

§ 371 Date: Oct. 5, 2023

(51) Int. Cl. H05B 6/66; H02J 3/00

(52) U.S. Cl. CPC H05B 6/664; H02J 3/001

(57) ABSTRACT

Household appliance comprising: first power supply lines (4) which are connectable to an AC power supply source (5) for receiving a main electric power (P1) and providing a first AC voltage (V1) and a first AC current (I1). The household appliance, further comprises: a first load (8), and a second load (7) operating by a second voltage (Vcc) lower than the first AC voltage (V1), a master control circuit (12) operating by the second voltage (Vcc), which is configured to generate control signals (SC) to selectively control the first load (8) and the second load (7), and comprises a current sensor (12b) configured to measure the first AC current (I1) and provide a first value (K1(I1) indicative of the first AC current (I1), an inverter device (13) which is electrically connected to the first power supply lines (4) and to the master electronic control circuit (12) to receive the control signal (SC), and is configured to control the voltage supplied to first load (8) based on the control signal. The inverter device (13) further comprises a voltage measurement circuit (13b) configured to measure the first AC voltage (V1) and provide a second value (K2(V1)) indicative of the first AC voltage (V1). The inverter device (13) is configured to provide the second value (K2(V1)) to the master control circuit (12) by a opto-isolator electronic module (15). The master control circuit (12) is configured to determine a third value (K3(P1)) indicative of the main electric power (P1) based on the first value (K1(I1)) and the second value (K2(V1)).

The present invention relates to a household appliance and an operating method thereof.

More specifically, the present invention concerns the real-time measurement of the electric power supplied to a household appliance, to which the following description will makes explicit reference without however losing in generality.

### BACKGROUND ART

It is known the need to monitor the electric power, and in particular, both the voltage and the current supplied to a household appliance from the external public power supply grids in order to detect critical electric conditions generated in the public grids themselves.

In fact, it may happen that an overvoltage condition generated in the public power supply grid causes, on the one hand, damage to electronic circuits or devices of the household appliance, and on the other hand a potentially dangerous condition for users.

In recent years, the frequency of the aforementioned critical conditions of sudden overvoltage has increased especially in some countries wherein domestic and industrial users in adjacent areas, are locally connected to the same power distribution point/cabin.

It often happens that a request for an increase of energy by industrial users determines an electric power peak in the electric power distribution point which exposes the household appliances of domestic users to electric critical conditions, such as over-voltages.

Moreover, it may happen that connection errors on the electric lines e/o on electric power distribution point during maintenance operations may cause accidental over-voltages on the grid, damaging the electronic circuits of the refrigerators.

Aim of the present invention is therefore, on the one side, to overcome the technical problems referred above, and on the other sides to satisfy the need to monitor in real time the electric power that household appliances receive from a public power supply grid.

### DISCLOSURE OF INVENTION

In compliance with the above aims, according to the present invention there is provided a household appliance comprising: first power supply lines which are connectable to an AC power supply source for receiving a main electric power from said AC power supply source and for providing a first AC voltage and a first AC current, at least a first load, at least a second load operating by a second voltage lower than said first AC voltage, a master control circuit operating by said second voltage, which is configured to generate control signals to selectively control said first load and second load, and comprises a current measuring sensor configured to measure said first AC current and provide a first value indicative of said first AC current, an inverter device which is electrically connected to said first power supply lines for receiving said first AC voltage and to said master electronic control circuit to receive said control signal, and is configured to control the voltage supplied to said first load based on said control signal, said inverter device further comprises a voltage measurement circuit configured to measure said first AC voltage and provide a second value indicative of said first AC voltage; the inverter device is configured to provide said second value to said master control circuit by opto-isolator electronic means, said master control circuit is configured to determine a third value indicative of said main electric power based on said first value and second value.

The Applicant has found that connecting the master control circuit to the inverter device via the opto-isolator module allows to maintain electrically safe the master control circuit and in particular the loads. The technical effect obtained by using the opto-isolator module to connect the master control circuit to the inverter device is, on the one hand, to electrically isolate the electric loads from the main power lines having the first AC voltage potentially dangerous for users, and, on the other hand, using the measurement circuit comprised in the inverter device.

Indeed, arranging a voltage measurement circuit in the master control circuit would increase the complexity and cost of the electronic control system. The electric insulation of the voltage measurement circuit in the master control circuit would increase the overall cost of the system, without guarantying completely the electric isolation of the low voltage loads from the first AC voltage. It is highlighted that loads, in use, are exposed to the risk of contact with users. Consequently, it is necessary to ensure that loads be powered by the low voltage. The use of the voltage measure circuit in the master control circuit, instead of the inverter device, could determine, in the event of a malfunction, the directly supply of the first voltage to the low voltage loads, causing a dangerous condition for users and loads. On the contrary, using the voltage measurement circuit of the inverter device in combination with the galvanic separation made by the opto-isolator module between the inverter device and the master control circuit as envisaged by the present invention, ensures a complete electric isolation of the latter and the loads from the inverter device.

Preferably, said master control circuit is further configured to provide said control signal to said inverter device by said opto-isolator electronic means.

Preferably, said opto-isolator electronic means are comprised in said inverter device.

Preferably, said opto-isolator electronic means are comprised in said master control circuit.

Preferably, said opto-isolator electronic means are structured to maintain said master control circuit and said inverter device galvanically insulated from each other.

Preferably, the household appliance further comprises a voltage transformer module which comprises input terminals connected to said power supply lines, and output terminals connected to said master control circuit, said voltage transformer module being configured to transform said first AC voltage in said second voltage to be supplied to said master control circuit and or to said second loads and is structured to maintain electrically isolated said master control circuit and/or said second loads from said power supply lines.

Preferably, said current measuring sensor comprises a Hall Effect sensor.

Preferably, said master control circuit is configured to determine in real-time said main electric power based on said first value and second value.

Preferably, said master control circuit is configured to determine an overvoltage supply condition of said first power supply lines based on said second value.

Preferably, said master control circuit is configured to determine an anomalous operation condition or a malfunction condition of said first loads and/or second loads based on said main electric power.

Preferably, said household appliance is a refrigerator appliance and said first load comprises at least one among: a compressor unit, and a defrost heating resistor, and said second load comprises at least one among: a control panel and a illuminating circuit.

Preferably, said household appliance is a laundry washing machine and said first load comprises at least one among: a drain pump, a recirculation pump a drum motor circuit and a heating resistor, said second load comprises at least one among: a control panel and a illuminating circuit.

Preferably, said appliance is an oven and said first load comprises at least one among: a heating resistor, a fan motor a microwave generator unit, said second load comprises at least one among: a control panel and a illuminating circuit.

Preferably, said appliance is a laundry dryer machine and said first load comprises at least one among: heating resistor, drum motor circuit, compressor unit, a motor fan, said second load comprises at least one among: a control panel and a illuminating circuit.

The present invention further concerns to a method of operating of a household appliance comprising: first power supply lines which are connectable to an AC power supply source for receiving a main electric power from said AC power supply source and for providing a first AC voltage and a first AC current, at least a first load, at least a second load operating by a second voltage lower than said first AC voltage, a master control circuit operating by said second voltage, which is configured to generate control signals to selectively control said first load and second load, an inverter device, which is electrically connected to said first power supply lines for receiving said first AC voltage and said first AC current and to said master control circuit to receive said control signal, and is configured to control the voltage supplied to said first load based on said control signal; the method comprises the steps of: measuring by a current sensor of the master control circuit a first AC current and providing a first value indicative of said first AC current, measuring by a voltage measurement circuit of said inverter device said first AC voltage and providing a second value indicative of said first AC voltage, providing said second value from said inverter device to said master control circuit by opto-isolator electronic means, determining by said master control circuit said main electric power based on said first and second value.

As described above, the combined use of the voltage measure circuit of the inverter device to measure the first AC voltage and the galvanic separation between the inverter device and the master control circuit made by the opto-isolator module allows, on the one hand, to reduce the cost of the electronic system, and on the other hand, reducing the risk that the low voltage loads can be affected by the dangerous first AC voltage V1.

Preferably, said master control circuit is further configured to provide said control signal to said inverter device by said opto-isolator electronic means.

Preferably, said opto-isolator electronic means are comprised in said inverter device.

Preferably, said opto-isolator electronic means are comprised in said master control circuit.

Preferably, said opto-isolator electronic means are structured to maintain said master control circuit and said inverter device galvanically insulated from each other.

Preferably, the household appliance further comprises a voltage transformer module which comprises input terminals connected to said power supply lines, and output terminals connected to said master control circuit, said voltage transformer module being configured to transform said first AC voltage in said second voltage to be supplied to said master control circuit and or to said second loads and is structured to maintain electrically isolated said master control circuit and/or said second loads from said power supply lines.

Preferably, said current measuring sensor comprises a Hall Effect sensor.

Preferably, said master control circuit is configured to determine in real-time said main electric power based on said first value and second value.

Preferably, said master control circuit is configured to determine an overvoltage supply condition of said first power supply lines based on said second value.

Preferably, said master control circuit is configured to determine an anomalous operation condition or a malfunction condition of said first loads and/or second loads based on said main electric power.

Preferably, said household appliance is a refrigerator appliance and said first load comprises at least one among: a compressor unit, and a defrost heating resistor, and said second load comprises at least one among: a control panel and a illuminating circuit.

Preferably, said household appliance is a laundry washing machine and said first load comprises at least one among: a drain pump, a recirculation pump a drum motor circuit and a heating resistor, said second load comprises at least one among: a control panel and a illuminating circuit.

Preferably, said appliance is an oven and said first load comprises at least one among: a heating resistor, a fan motor a microwave generator unit, said second load comprises at least one among: a control panel and a illuminating circuit.

Preferably said appliance is a laundry dryer machine and said first load comprises at least one among: heating resistor, drum motor circuit, compressor unit, a motor fan, said second load comprises at least one among: a control panel and a illuminating circuit.

### BRIEF DESCRIPTION OF THE DRAWINGS

Further characteristics and advantages of the present invention will be highlighted in greater detail in the following detailed description of some of its preferred embodiments, provided with reference to the enclosed drawings.

A non-limiting embodiment of the present invention will now be described, by way of example, with reference to the accompanying drawings, in which:

FIG. 1 is a schematic view illustrating a household appliance with a schematized electronic control system, realized in accordance with the teachings of the present invention;

FIG. 2 is a block diagram of the electronic control system of the household appliance shown in FIG. 1.

### DETAILED DESCRIPTION OF THE INVENTION

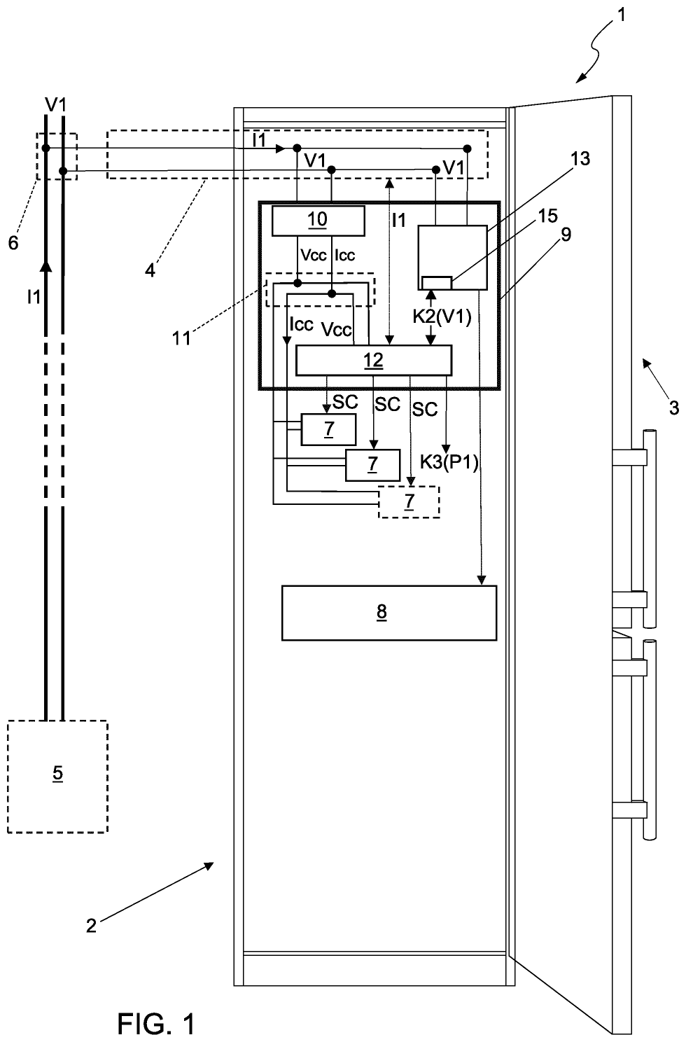

The present invention has proved to be particularly advantageous when applied to household appliance corresponding to a refrigerator appliance designed to be supplied with AC voltage and provided with an electronic system configured to determine conveniently in real-time the electric power absorbed by the refrigerator appliance itself (i.e. the overall power consumption of the refrigerator appliance). However, it should in any case be underlined that the present invention is not limited to a refrigerator appliance. Indeed, the present invention can be conveniently applied to other kind of household appliances (domestic appliances), like for example laundry washing machines, drying machines and ovens.
With reference to FIG. 1, reference number 1 denotes as a whole a household electric appliance corresponding to a refrigerator appliance. The refrigerator appliance 1 is adapted for preserving perishable foodstuff and preferably suitable for domestic use, i.e. a household refrigerator.

Refrigerator appliance 1 comprises a preferably substantially parallelepiped-shaped, self-supporting cabinet 2, which has a thermal-insulating structure and is internally provided with at least one, preferably substantially parallelepiped-shaped, thermal-insulated storage cavity which is adapted to accommodate food-stuff and communicates with the outside via a large, preferably roughly rectangular-shaped, access opening which is located on a main face/wall of the same cabinet 2.

The refrigerator appliance 1 further comprises at least one door 3 (two doors in the illustrated example in FIG. 1) that has a thermal-insulating structure and is flag hinged to the cabinet 2, so as to be manually rotatable to and from a closing position in which the door abuts on said main face/wall of the cabinet 2 to substantially airtight close/seal the access opening of said storage cavity. In the example shown, in particular, the self-supporting cabinet 2 is preferably structured for stably resting on the floor/ground.

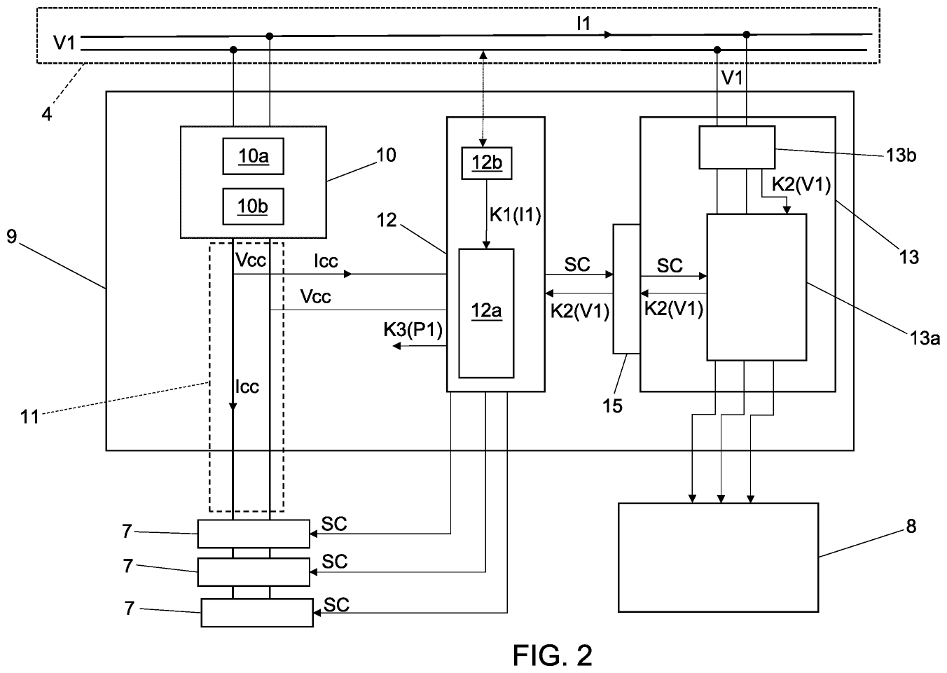

With reference to FIGS. 1 and 2, the refrigerator appliance 1 further comprises power supply lines 4 which are connectable to an AC power supply source 5 for receiving a main electric power from the AC power supply source 5 and for providing a first AC voltage V1 and a first AC current I1. In the exemplary embodiment of FIG. 2 the power supply lines 3 are electrically coupled to a power socket 6, e.g. by means of an AC power cord (not illustrated), for receiving electric power from an AC power supply source 5.

The power supply lines 4 preferably comprise a first and second power lines having the first AC voltage V1 from each other (line and neutral). The first AC voltage V1 between the first and second lines may oscillates, for example at a frequency of 50 or 60 Hz, causing the first AC current I1 to flow across a generic electric load when connected between lines. The first AC voltage may be for example about 127 Volt or 220 Volt.

It is understood that in the present document, the term AC power source 5, means any known means/structures/units/apparatuses for generating and/or transforming, and/or delivering, and/or converting AC electric power (wherein AC is the acronym of Alternating Current). In the example shown in FIG. 1, the electric power supplied by the AC power source 5 is provided to the refrigerator appliance 1 by the power socket 6 (schematically illustrated in FIGS. 1 and 2).

It is understood that the AC power supply source 5 may be an interconnected network (electric grid) for delivering electricity from suppliers to consumers, which comprises, for example, public available AC power supplies, that produce electric power, preferably high-voltage transmission grids comprising high-voltage transmission lines for carrying power from the (typically distant) public available AC power supplies to demand centers, and, preferably, medium-voltage distribution grids for connecting individual customers, such as the building wherein the power socket 6 is located.

According to the exemplary embodiment illustrated in FIG. 1, the household appliance 1 comprises one or more electric loads 7 and one or more electric loads 8.

With reference to FIGS. 1 and 2, in the example shown, the electric loads 8 may comprise: a compressor unit for the circulating refrigerant and/or a heating resistor for performing defrost cycles.

With reference to FIGS. 1 and 2, in the example shown, the electric loads 7 may comprise: a control panel and/or an illuminating circuit provided with light sources, for example LED-sourced arranged inside thermal-insulated storage cavity.

According to the exemplary embodiment illustrated in FIG. 1, the refrigerator appliance 1 comprises an electronic control system 9, which is configured to selectively control the electric loads 7 and the electric loads 8 based on the implemented refrigerating program.

The electronic control system 9 may comprise a voltage conversion circuit 10 which is electrically connected by input terminals with the power supply lines 4 for receiving the first AC voltage V1 and the first AC current I1 and is electrically connected by output terminals with second supply lines 11 to provide a second voltage Vcc and a second current Icc.

According to an exemplary embodiment the voltage conversion circuit 10 is configured to transform, rectify and regulate the first AC voltage V1 received from power supply lines 4 (line and neutral) and provides the second voltage Vcc and second current Icc to the second supply lines 11. The second voltage is lower than said first AC voltage. The second voltage is a low voltage preferably a DC Voltage having a value among: 3V, 5V or 12V (DC voltage) with respect to a prefixed reference voltage, for example a ground voltage.

The voltage conversion circuit 10 may comprise for example: a voltage magnetic transformer 10a having the primary circuit electrically connected to the power supply lines 4 for receiving the first AC voltage and a secondary circuit providing a reduced AC voltage. The voltage conversion circuit 10 may further comprise a AC/DC rectifying and regulating unit 10b which comprise input terminals electrically connected to the secondary circuit of the voltage magnetic transformer 10a for receiving the reduced AC voltage and output terminals electrically connected to second supply lines 11 to provide to the latter the second voltage Vcc and second current Icc.

The electronic control system 9 further comprises a master control circuit 12 and an inverter device 13. The master control circuit 12 is designed to supervise and manage the operations performed by the refrigerator appliance. In the exemplary embodiment of the present invention, the master control circuit 12 is configured to generate control signals SC to selectively control the electric loads 7 and the electric load 8.

According to the preferred embodiment of the present invention, the master control circuit 12 is electrically connected with the second supply lines 11 for being supplied by the second voltage Vcc and with the electric loads 7 to provide the latter with the respective control signals SC.

The master control circuit 12 may comprise an electronic processing unit 12a, i.e. a microprocessor, configured to generate the control signals SC to be used to control the electric loads 7 and 8. The master control circuit 12 may further comprise a current sensor 12b. The current sensor 12b is configured to measure the first AC current I1, which crosses the power supply lines 4. The current sensor 12b is configured to provide to the electronic processing unit 12a a first value K1(I1), which is indicative of the first AC current I1, measured on the power supply lines 4. Conveniently, the current sensor 12b is a Hall Effect sensor. The Hall Effect sensor is configured to sense the magnetic field generated by the passage of the first AC current I1 across the power supply lines 4. The Hall Effect sensor is configured to provide a corresponding electric signal containing the first value K1(I1). The first value K1(I1) may corresponds, for example, to a voltage proportional to the sensed magnetic field depending on the first AC current I1. The current sensor 12b may conveniently corresponds to the current sensor described in the European invention patent application n. EP3542433A1 of the Applicant, the contents of which (description and Figures) are hereby understood to be fully incorporated by reference.

With reference to FIGS. 1 and 2, the inverter device 13 is electrically connected to the power supply lines 4 for receiving the first AC voltage V1 and first AC current I1 and is configured to drive the electric load 8. The inverter device 13 is further configured to receive in input the control signal SC and controls the AC voltage and AC current supplied to the electric load 8 based on the received control signal SC.

The inverter device 13 comprises a processing circuit 13a, i.e. a microprocessor, which supervises and manages the operations to control the voltage and current supplied to the electric load 8, based on the control signals.

The inverter device 13 further comprises a voltage measurement circuit 13b configured to measure the first AC voltage on the power supply lines 4. The voltage measurement circuit 13b is configured to provide a second value K2(V1) indicative of the measured first AC voltage V1. The voltage measurement circuit 13b is electrically connected with the processing circuit 13a and provides to the latter an electric signal containing the second value K2(V1).

According to a preferred embodiment of the present invention, the electronic control system 9 further comprise a opto-isolator module 15 which connects the inverter device 13 with the master control circuit 12 to which provides the second value K2(V1).

According to an exemplary embodiment illustrated in FIGS. 1 and 2, the opto-isolator module 15 is electrically arranged/integrated in the inverter device 13 and comprise terminals electrically connected to the processing circuit 13a and terminals electrically connected to the electronic processing unit 12a by means of connection lines (electric wires).

The opto-isolator module 15 is configured to receive the electric signals containing the second value K2(V1) from the processing circuit 13a, transform the electric signals in light signals, convert the transformed light signals in the electric signals, and provide the electric signals to the electronic processing unit 12a. The opto-isolator module 15 is also is configured to receive the electric signals containing the control signal SC from the electronic processing unit 12a transform the electric signals in light signals, convert the transformed light signals in the electric signals, and provide the electric signals to the processing circuit 13a. In other words, the opto-isolator module 15 may be conveniently bidirectional.

According to the preferred embodiment of the present invention, the electronic processing unit 12a of the master control circuit 12 is further configured to receive the first value K1(I1) from the current sensor 12b and receive the second value K2(V1) from the inverter device 13 via the terminal connected to the opto-isolator module 15.

According to the preferred embodiment of the present invention, the electronic processing unit 12a of the master control circuit 12 is further configured to determine a third value K3(P1) indicative of the main electric power based on the first K1(I1) and second value K2(V1). According to the preferred embodiment of the present invention, the electronic processing unit 12a of the master control circuit 12 is configured to determine the first AC current I1 based on the first value K1(I1), determine the first AC voltage V1 based on the second value K2(V1) and determine the power P1 multiplying the first AC current I1 by the first AC voltage V1.

According to the preferred embodiment of the present invention, the electronic processing unit 12a of the master control circuit 12 is further configured to determine the third value indicative of the main electric power in real-time.

Preferably, the electronic processing unit 12a may be configured to determine, based on the first and second value, the following values: the real power, and/or the apparent power, and or the reactive power, and/or the power factor.

The Applicant has found that connecting the master control circuit 12 to the inverter device 13 via the opto-isolator module 15 allows to maintain electrically safe the master control circuit 12 and in particular the loads 7.

The technical effect obtained by using the opto-isolator module 15 to connect the master control circuit 12 to the inverter device 13 is, on the one hand, to electrically isolate the electric loads 7 from the main power lines 4 having the first AC voltage V1 potentially dangerous for users, and, on the other hand, using the measurement circuit 13a comprised in the inverter device 13.

Indeed, arranging a voltage measurement circuit in the master control circuit 12 would increase the complexity and cost of the electronic control system 19. The electric insulation of the voltage measurement circuit in the master control circuit 12 would increase the overall cost of the system, without guarantying completely the electric isolation of the low voltage loads 7 from the first AC voltage V1.

It is highlighted that loads 7, in use, are exposed to the risk of contact with users. Consequently, it is necessary to ensure that loads 7 be powered by the low voltage. The use of the voltage measure circuit in the master control circuit 12, instead of the inverter device 13, could determine, in the event of a malfunction, the directly supply of the first voltage to the low voltage loads 7, causing a dangerous condition for users and loads 7. On the contrary, using the voltage measurement circuit 13a of the inverter device 13 in combination with the galvanic separation made by the opto-isolator module 15 between the inverter device 13 and the master control circuit 12 as envisaged by the present invention, ensures a complete electric isolation of the latter and the loads 7 from the inverter device 13.

The opto-isolator module 15 may comprise electronic component configured to transfer electric signals between two isolated circuits by using light. The opto-isolator module 15 may comprise the electro-optical devices such as: optocoupler components, electronic photocoupler components, electro-optical isolator components or similar.

According to an alternative embodiment (not illustrated), the opto-isolator module 15 instead of being arranged in the inverter device 13, may be arranged/integrated in the master control circuit 12.

According to an embodiment, the electronic processing unit 12a of the master control circuit 12 may be also configured to determine an overvoltage supply condition of the power supply lines 4 (and of the refrigerator appliance 1) based on the second value K2(V1). i.e. based on the first AC tension V1.

According to an advantageous embodiment of the present invention the electronic processing unit 12a of the master control circuit 12 may be further configured to determine an anomalous operation condition or a malfunction condition of the loads 7 and/or the loads 8 based on the determined main electric power.

According to an advantageous embodiment of the present invention the electronic processing unit 12a of the master control circuit 12 may be further configured to determine an anomalous operation condition or a malfunction condition of the inverter device 13 based on the determined main electric power.

The method of operation of the refrigerator appliance 1 envisages to implement the following steps: measuring by the current sensor 12b of the master control circuit 12 the first AC current I1 which flows across the AC power supply lines 4 and provides the first value K1(I1) indicative of the measured current I1 to the electronic processing unit 12a; measuring by the voltage measuring circuit 13b of the inverter device 13 the first AC voltage V1 on the AC power supply lines 4, providing by the opto-isolator module 15 the second value K2(V1) indicative of the first AC voltage V1 to the electronic processing unit 12a, determining preferably in real time by the electronic processing unit 12a, the third value K3(P1) indicative of the main electric power P1, based on the first value K1(I1) and the second value K2(V1).

As described above, the combined use of the voltage measure circuit of the inverter device to measure the first AC voltage and the galvanic separation between the inverter device and the master control circuit made by the opto-isolator module allows, on the one hand, to reduce the cost of the electronic system, and on the other hand, reducing the risk that the low voltage loads can be affected by the dangerous first AC voltage V1.

Clearly, changes may be made to the refrigerator appliance 1 without, however, departing from the scope of the present invention.

According to a possible different embodiment (not shown), the household appliance is a laundry washing machine. According to this embodiment, possible non-limitative examples of electric loads 8 may comprise: a motor for rotating a washer drum, a drain pump for draining washing liquid from a washing tub, a recirculation pump for recirculating washing liquid, and a heating resistor for heating washing liquid. According to this embodiment, possible non-limitative examples of low voltage electric loads 7 may comprise: control panel, and/or an illuminating circuit provided with light sources arranged inside the washing tube (i. e. LED sources).

According to a possible different embodiment (not shown), the household appliance is a laundry dryer machine. According to this embodiment, possible non-limitative examples of electric loads 8 may comprise: a motor for rotating a dryer drum, a fan for propelling drying air, a heating resistor for heating drying air, and a compressor for the heat pump circuit. In case the household appliance 1 is laundry dyer machine the electric loads 7 may comprise a control panel, and an illuminating circuit provided with light sources.

According to a possible different embodiment (not shown), the household appliance is an oven, According to this embodiment, possible non limitative examples of electric loads 8 may comprise a heating resistor for heating a cooking chamber, a microwave generator for generating microwaves radiation to be provided in the cooking chamber, and a fan for circulating air inside the cooking chamber. If the electric appliance is an oven, possible non-limitative examples of electric loads 7 may comprise a control panel and illuminating circuits.

1. Household appliance comprising:
first power supply lines (4) which are connectable to an AC power supply source (5) for receiving a main electric power (P1) from said AC power supply source (5) and for providing a first AC voltage (V1) and a first AC current (I1),
at least a first load (8),
at least a second load (7) operating by a second voltage (Vcc) lower than said first AC voltage (V1),
a master control circuit (12) operating by said second voltage (Vcc), which is configured to generate control signals (SC) to selectively control said first load (8) and second load (7), and comprises a current measuring sensor (12b) configured to measure said first AC current (I1) and provide a first value (K1(I1) indicative of said first AC current (I1),
an inverter device (13) which is electrically connected to said first power supply lines (4) for receiving said first AC voltage (V1) and to said master electronic control circuit (12) to receive said control signal (SC), and is configured to control the voltage supplied to said first load (8) based on said control signal (SC), said inverter device (13) further comprises a voltage measurement circuit (13b) configured to measure said first AC voltage (V1) and provide a second value (K2(V1)) indicative of said first AC voltage (V1),
said household appliance being characterized in that:
said inverter device (13) is configured to provide said second value (K2(V1) to said master control circuit (12) by opto-isolator electronic means (15),
said master control circuit (12) is configured to determine a third value (K3(P1)) indicative of said main electric power (P1) based on said first value (K1(I1)) and second value (K2(V1)).

2. Household appliance according to claim 1, wherein said master control circuit (12) is further configured to provide said control signal (SC) to said inverter device (13) by said opto-isolator electronic means (15).

3. Household appliance according to claim 1, wherein said opto-isolator electronic means (15) are comprised in said inverter device (13).

4. Household appliance according to claim 1, wherein said opto-isolator electronic means (15) are comprised in said master control circuit (12).

5. Household appliance according to claim 1, wherein said opto-isolator electronic means (15) are structured to maintain said master control circuit (12) and said inverter device (13) galvanically insulated from each other.

6. Household appliance according to claim 1, comprising a voltage transformer module (12b) which comprises input terminals connected to said power supply lines (4), and output terminals connected to said master control circuit (12), said voltage transformer module (12b) being configured to transform said first AC voltage (V1) in said second voltage (Vcc) to be supplied to said master control circuit (12) and or to said second loads (7) and is structured to maintain electrically isolated said master control circuit (12) and/or said second loads (7) from said power supply lines (4).

7. Household appliance according to claim 1, wherein said current measuring sensor (12b) comprises a Hall Effect sensor.

8. Household appliance according to claim 1, wherein said master control circuit (12) is configured to determine in real-time said main electric power (P1) based on said first value (K1(I1)) and second value (K2(V1)).

9. Household appliance according to claim 1, wherein said master control circuit (12) is configured to determine an overvoltage supply condition of said first power supply lines (4) based on said second value (K2(V1)).

10. Household appliance according to claim 1, wherein said master control circuit (12) is configured to determine an anomalous operation condition or a malfunction condition of said first loads (8) and/or second loads (7) based on said main electric power (P1).

11. Household appliance according to claim 1, wherein said appliance is a refrigerator appliance and
said first load (8) comprises at least one among: a compressor unit, and a defrost heating resistor, and
said second load (7) comprises at least one among: a control panel and a illuminating circuit.

12. Household appliance according to claim 1, wherein said appliance is a laundry washing machine and
said first load (8) comprises at least one among: a drain pump, a recirculation pump a drum motor circuit and a heating resistor,
said second load (7) comprises at least one among: a control panel and a illuminating circuit.

13. Household appliance according to claim 1, wherein said appliance is an oven and
said first load (8) comprises at least one among: a heating resistor, a fan motor a microwave generator unit,
said second load (7) comprises at least one among: a control panel and a illuminating circuit.

14. Household appliance according to claim 1, wherein said appliance is a laundry dryer machine and
said first load (8) comprises at least one among: heating resistor, drum motor circuit, compressor unit, a motor fan,
said second load (7) comprises at least one among: a control panel and a illuminating circuit.

15. Method of operating of a household appliance comprising:
first power supply lines (4) which are connectable to an AC power supply source (5) for receiving a main electric power (P1) from said AC power supply source (5) and for providing a first AC voltage (V1) and a first AC current (I1),
at least a first load (8),
at least a second load (7) operating by a second voltage (Vcc) lower than said first AC voltage (V1),
a master control circuit (12) operating by said second voltage (Vcc), which is configured to generate control signals (SC) to selectively control said first load (8) and second load (7),
an inverter device (13), which is electrically connected to said first power supply lines (4) for receiving said first AC voltage (V1) and said first AC current (I1) and to said master control circuit (12) to receive said control signal (SC), and is configured to control the voltage supplied to said first load (8) based on said control signal (SC),
the method being characterized by:
measuring by a current sensor (12b) of the master control circuit (12) a first AC current (I1) and providing a first value (K1(I1)) indicative of said first AC current (I1),
measuring by a voltage measurement circuit (13b) of said inverter device (13) said first AC voltage (V1) and providing a second value (K2(V1)) indicative of said first AC voltage (V1),
providing said second value (K2(V1)) from said inverter device (13) to said master control circuit (12) by opto-isolator electronic means (15),
determining by said master control circuit (12) said main electric power (1) based on said first (K1(I1)) and second value (K2(V1)).
